(19) United States
(12) Patent Application Publication
(10) Pub. No.: US 2013/0162286 A1
(43) Pub. Date: Jun. 27, 2013

(54) IMPEDANCE CODE GENERATION CIRCUIT AND SEMICONDUCTOR MEMORY DEVICE INCLUDING THE SAME

(71) Applicant: Geun-Il LEE, Gyeonggi-do (KR)

(72) Inventor: Geun-Il LEE, Gyeonggi-do (KR)

(21) Appl. No.: 13/595,427

(22) Filed: Aug. 27, 2012

(30) Foreign Application Priority Data
Dec. 21, 2011 (KR) 10-2011-0139603

(51) Int. Cl. H03K 19/003

(52) U.S. Cl. 326/30

(57) ABSTRACT

An impedance code generation circuit includes an impedance code generation unit configured to generate an impedance code, a set value generation unit configured to generate a set value by counting an external signal, and an impedance code modification unit configured to generate a modified impedance code by performing a logic operation on the set value and the impedance code.

### CROSS-REFERENCE TO RELATED APPLICATIONS

The present application claims priority of Korean Patent Application No. 10-2011-0139603, filed on Dec. 21, 2011, which is incorporated herein by reference in its entirety.

### BACKGROUND

1. Field

Exemplary embodiments of the present invention relate to a semiconductor device, and more particularly, to an impedance code generation circuit for generating an impedance code for impedance matching in a semiconductor device.

2. Description of the Related Art

Diverse semiconductor devices that are provided as integrated circuit chips, such as a Central Processing Unit (CPU), a memory, and a gate array, are integrated with diverse electrical products, such as a personal computer (PC), a server, and a workstation. In most cases, a semiconductor device includes an input circuit for receiving various external signals through an input pad and an output circuit for providing internal signals to the outside through an output pad.

Meanwhile, as the electrical products come to operate faster and faster, the swing width of a signal transferred between semiconductor devices is being decreased in order to minimize the delay time taken for signal transfer. However, as the swing width of the signal is decreased, the influence of external noise on the signal becomes greater, and signal reflection originating from impedance mismatch at an interface becomes more serious. The impedance mismatch is caused by external noise, variation in power supply voltage, a change in operation temperature, and a change in a fabrication process. The impedance mismatch makes it difficult to transfer data at a high data transfer rate and it may distort an output data outputted from a data output terminal of a semiconductor device. Therefore, when a semiconductor device on a receiving part receives the distorted output signal through its input terminal, setup/hold failure or an input level decision error may occur frequently.

In particular, memory devices, which operate at high operation speed, employ an impedance matching circuit, which is called an on-die termination, around a pad in an integrated circuit chip in order to address the above-mentioned errors. A typical on-die termination scheme includes a source termination performed by an output circuit on a transferring part and on a receiving part, includes a parallel termination performed by termination circuits that are coupled in parallel to a receiving circuit coupled with the input pad.

ZQ calibration means a process of generating an impedance code that varies as process, voltage, and temperature conditions (PVT) are changed. A termination impedance value is controlled based on the impedance code generated as a result of the ZQ calibration. An external resistance is typically coupled to a pad, which is referred to as a ZQ pad, to be used as standard for calibration. For this reason, a term ‘ZQ calibration’ is usually used.

Hereinafter, an impedance code generation circuit for generating an impedance code, and a termination circuit for terminating an input/output node based on the generated impedance code are described.

FIG. 1 is a schematic diagram of a conventional impedance code generation circuit. The conventional impedance code generation circuit includes a first pull-up reference impedance unit 110, a second pull-up reference impedance unit 120, a pull-down reference impedance unit 130, a reference voltage generator 102, first and second comparison units 103 and 104, and first and second counters 105 and 106.

To have a look at the operations of the constituent elements, the first comparator 103 generates up/down signals UP/DOWN by comparing a voltage of a calibration node ZQ which is generated by voltage division of an external resistor 101 and the first pull-up reference impedance unit 110 with a reference voltage VREF. For example, an approximately 240Ω of the external resistor 101 is coupled with a calibration pad ZQ PAD and the reference voltage VREF, generally set to ½VDDQ, is generated in the internal reference voltage generator 102.

The first counter 105 receives the up/down signals UP/DOWN and generates a pull-up impedance code PCODE<0:N>. The pull-up impedance code PCODE<0:N> controls the total impedance value of the first pull-up reference impedance unit 110 by turning on/off the parallel resistors in the first pull-up reference impedance unit 110. Here, the impedance value of each of the parallel resistors is designed depending on a binary weight of the impedance code inputted thereto. The controlled impedance value of the first pull-up reference impedance unit 110 affects the voltage of the calibration node ZQ again and the above operation is repeated. In short, the pull-up impedance code PCODE<0:N> is counted until the total impedance value of the first pull-up reference impedance unit 110 becomes the same as the impedance value of the external resistor 101. This is referred to as a pull-up calibration operation.

The pull-up impedance code PCODE<0:N> generated from the above-described pull-up calibration operation is inputted to the second pull-up reference impedance unit 120 to decide the total impedance value of the second pull-up reference impedance unit 120. Then, a pull-down calibration operation begins. The pull-down calibration operation is similar to the pull-up calibration operation. The voltage of a node A is calibrated by using the second comparator 104 and the second counter 106 until it is equal to the reference voltage VREF, in other words, the total impedance value of the pull-down reference impedance unit 130 becomes the same as the total impedance value of the second pull-up reference impedance unit 120.

The impedance codes PCODE<0:N> and NCODE<0:N> generated as a result of the above-described ZQ calibration operations are inputted to a termination circuit (see FIG. 2) and used for controlling a termination impedance value.

FIG. 2 is a block view of a conventional termination circuit. The termination circuit receives impedance codes PCODE<0:N> and NCODE<0:N> that are generated in the impedance code generation circuit shown in FIG. 1 and terminates an interface pad.

A termination circuit includes a pull-up termination unit 210 and a pull-down termination unit 220. The termination circuit may include only the pull-up termination unit 210 or the pull-down termination unit 220.

The pull-up termination unit 210 is designed similarly to the first pull-up reference impedance unit 110 and receive the pull-up impedance code PCODE<0:N>. Therefore, the impedance value of the pull-up termination unit 210 has the same tendency as the first pull-up reference impedance unit 110. Although the pull-up termination unit 210 may have the same impedance value as the first pull-up reference impedance unit 110, which is approximately 240Ω, the pull-up termination unit 210 may be controlled to have an impedance value of approximately 120Ω or approximately 60Ω through scaling. A pull-up termination enable signal PU_EN is a signal for turning on/off the pull-up termination unit 210. In short, whether to turn on/off the pull-up termination unit 210 is decided based on the pull-up termination enable signal PU_EN, and what impedance value the pull-up termination unit 210 is to have when the pull-up termination unit 210 is turned on is decided based on the pull-up impedance code PCODE<0:N>.

The pull-down termination unit 220 is designed similarly to the pull-down reference impedance unit 130 and receive the pull-down impedance code NCODE<0:N>. Therefore, the impedance value of the pull-down termination unit 220 has the same tendency as the pull-down reference impedance unit 130. Although the pull-up termination unit 220 may have the same impedance value as the pull-down reference impedance unit 130, which is approximately 240Ω, the pull-down termination unit 220 may be controlled to have an impedance value of approximately 120Ω or approximately 60Ω through scaling. A pull-down termination enable signal PD_EN is a signal for turning on/off the pull-down termination unit 220. In short, whether to turn on/off the pull-down termination unit 220 is decided based on the pull-down termination enable signal PD_EN, and what impedance value the pull-down termination unit 220 is to have when the pull-down termination unit 220 is turned on is decided based on the pull-down termination code NCODE<0:N>.

The termination circuit shown in FIG. 2 may be an output driver for outputting data in a semiconductor device. When the pull-up termination enable signal PU_EN is enabled and the pull-up termination unit 210 pull-up terminates an interface pad, i.e., a DQ pad in the semiconductor device, a data of a logic high level is outputted from the DQ pad. When the pull-down termination enable signal PD_EN is enabled and the pull-down termination unit 220 pull-down terminates the DQ pad, a data of a logic low level is outputted from the DQ pad.

When the impedance codes PCODE<0:N> and NCODE<0:N> are generated as a result of the calibration operation in the impedance code generation circuit shown in FIG. 1 and the generated impedance codes PCODE<0:N> and NCODE<0:N> are inputted to the termination circuit shown in FIG. 2, the termination circuit of FIG. 2 is to have a target impedance value to matched with an external circuit out of the semiconductor device. However, in actuality, it frequently occurs that the impedance value of the termination circuit shown in FIG. 2 is greater than or smaller than the target impedance value.

This is because there is an error in the impedance code generation circuit shown in FIG. 1 and the impedance codes PCODE<0:N> and NCODE<0:N> are erroneously generated, or because there is a difference in terms of layout between the termination units of the termination circuit and the reference impedance units of the impedance code generation circuit. In addition, there may be other diverse factors. Since it is difficult to perfectly remove such factors, a method for controlling the impedance code value or the impedance value of the termination circuit depending on the impedance code value is being developed.

### SUMMARY

An embodiment of the present invention is directed to finding an accurate set value for correcting an impedance value and accurately correcting an impedance value based on the set value.

In accordance with an exemplary embodiment of the present invention, an impedance code generation circuit includes an impedance code generation unit configured to generate an impedance code, a set value generation unit configured to generate a set value by counting an external signal, and an impedance code modification unit configured to generate a modified impedance code by performing a logic operation on the set value and the impedance code.

In accordance with another exemplary embodiment of the present invention, a semiconductor memory device includes an impedance code generation unit configured to generate an impedance code, a set value generation unit configured to generate a set value by counting an external signal, an impedance code modification unit configured to generate a modified impedance code by performing a logic operation on the set value and the impedance code, and a termination circuit configured to determine an impedance value of an interface pad based on the modified impedance code.

### BRIEF DESCRIPTION OF THE DRAWINGS

FIG. 1 is a schematic diagram of a conventional impedance code generation circuit.

FIG. 2 is a block diagram of a conventional termination circuit.

FIG. 3 is a block diagram of a semiconductor device in accordance with an exemplary embodiment of the present invention.

FIG. 4 is a block diagram illustrating an impedance code generation circuit 300 shown in FIG. 3 in accordance with another exemplary embodiment of the present invention.

FIG. 5 is a block diagram illustrating an impedance code generation circuit 300 shown in FIG. 3 in accordance with yet another exemplary embodiment of the present invention.

### DETAILED DESCRIPTION

Exemplary embodiments of the present invention will be described below in more detail with reference to the accompanying drawings. The present invention may, however, be embodied in different forms and should not be construed as limited to the embodiments set forth herein. Rather, these embodiments are provided so that this disclosure will be thorough and complete, and will fully convey the scope of the present invention to those skilled in the art. Throughout the disclosure, like reference numerals refer to like parts throughout the various figures and embodiments of the present invention.

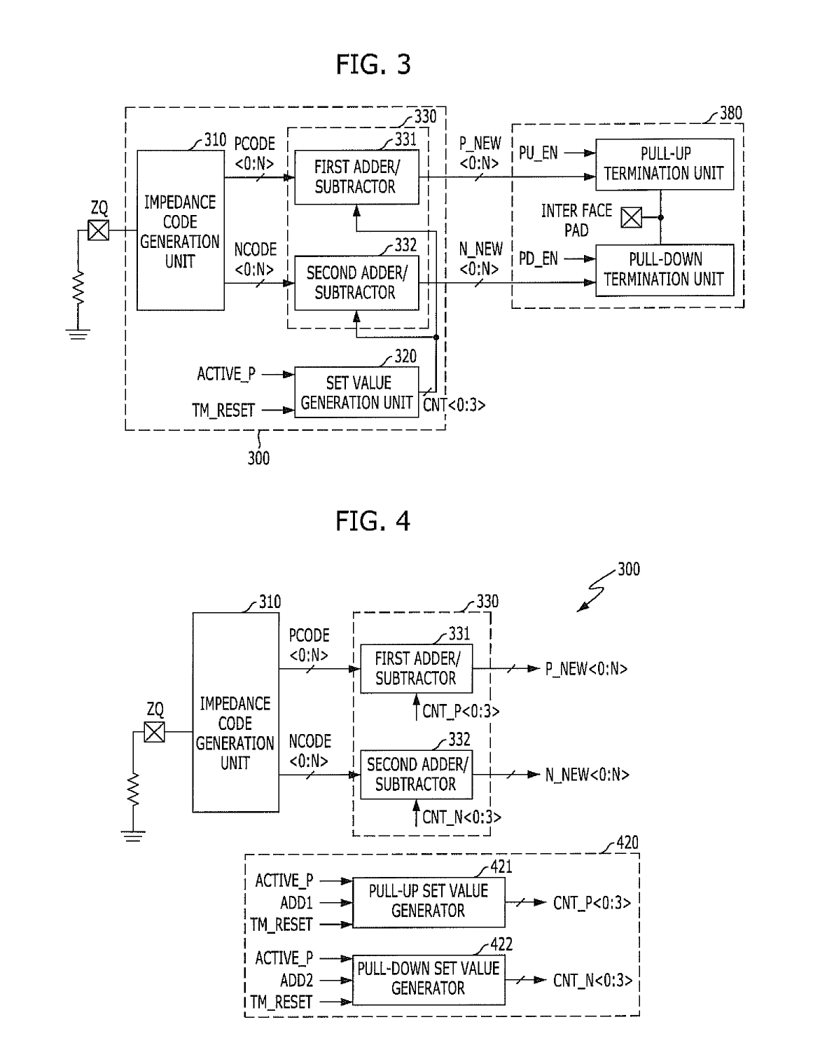

FIG. 3 is a block diagram of a semiconductor device in accordance with an exemplary embodiment of the present invention.

Referring to FIG. 3, the semiconductor device includes an impedance code generation circuit 300 and a termination circuit 380. The impedance code generation circuit 300 includes an impedance code generation unit 310, a set value generation unit 320, and an impedance code modification unit 330.

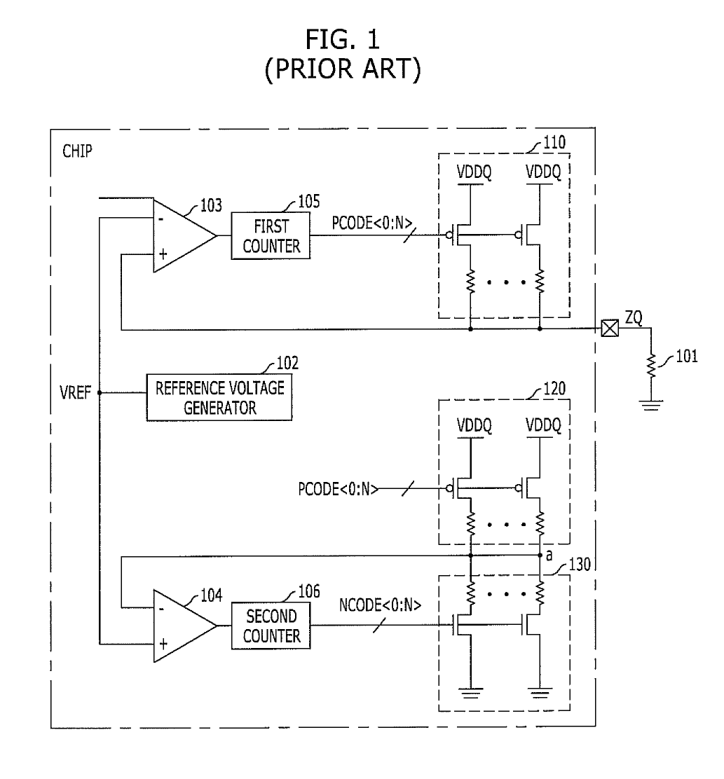

The impedance code generation unit 310 generates a pull-up impedance code PCODE<0:N> and a pull-down impedance code NCODE<0:N>. The impedance code generation unit 310 may be formed to be the same as the conventional impedance code generation circuit shown in FIG. 1, and it may be modified diversely as long as the impedance code generation unit 310 includes a structure for generating the pull-up impedance code PCODE<0:N> and the pull-down impedance code NCODE<0:N>.

The set value generation unit 320 generates a set value CNT<0:3> by counting how many times an external signal ACTIVE_P inputted from the outside of a chip is enabled. The external signal ACTIVE_P may be generated by any signal that is inputted from the outside of the semiconductor device. Illustrated here is a case that the semiconductor device is a memory device, and an active pulse ACTIVE_P which is enabled in the memory device whenever an active command is inputted from the outside of the memory device is presented as the external signal inputted from the outside of the chip. The set value generation unit 320 initializes the set value when a reset signal TM_RESET is enabled and generates the set value by counting the external signal while the reset signal TM_RESET is enabled. The set value generation unit 320 may be easily designed using a counter.

The impedance code modification unit 330 generates a modified pull-up impedance code P_NEW<0:N> by counting the set value CNT<0:3> generated in the set value generation unit 320 and the pull-up impedance code PCODE<0:N> and generates a modified pull-down impedance code N_NEW<0:N> by counting the set value CNT<0:3> and the pull-down impedance code NCODE<0:N>. To be specific, the impedance code modification unit 330 generates the modified pull-up impedance code P_NEW<0:N> and the modified pull-down impedance code N_NEW<0:N> by adding or subtracting the set value CNT<0:3> to or from the pull-up impedance code PCODE<0:N> and the pull-down impedance code NCODE<0:N>. The uppermost bit CNT<3> of the set value CNT<0:3> is used to decide whether to perform an addition operation or a subtraction operation, and the other bits CNT<0:2> are added or subtracted to or from the pull-up impedance code PCODE<0:N> and the pull-down impedance code NCODE<0:N>. For example, when the set value CNT<0:3> is ‘1011’, ‘011’ is added to the pull-up impedance code PCODE<0:N> and the pull-down impedance code NCODE<0:N>. When the set value CNT<0:3> is ‘0101’, ‘101’ is subtracted from the pull-up impedance code PCODE<0:N> and the pull-down impedance code NCODE<0:N>. The impedance code modification unit 330 may include a first adder/subtracter 331 and a second adder/subtracter 332.

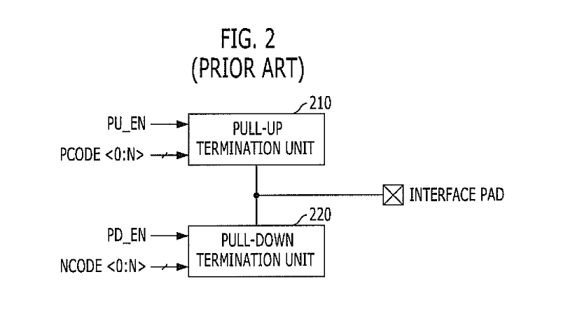

The termination circuit 380 may be formed to be the same as the termination circuit shown in FIG. 2. The termination circuit 380 of FIG. 3, however, is different in that it operates upon the receipt of the modified pull-up impedance code P_NEW<0:N> and the modified pull-down impedance code N_NEW<0:N>. The modified pull-up impedance code P_NEW<0:N> and the modified pull-down impedance code N_NEW<0:N> are modified codes that are tuned based on the set value CNT<0:3> which is generated by counting the number of times that the inputted external signal is enabled. Therefore, the termination circuit 380 may operate with more accurate impedance value, compared with the conventional termination circuit.

According to the exemplary embodiment of the present invention, the set value CNT<0:3> is generated by counting the external signal ACTIVE_P, and the pull-up impedance code PCODE<0:N> and the pull-down impedance code NCODE<0:N> are modified based on the set value CNT<0:3>. Therefore, when the termination circuit 380 does not have a target impedance value, the termination circuit 380 may be tuned to have the target impedance value by inputting the external signal ACTIVE_P from the outside of the semiconductor device.

Although FIG. 3 illustrates a case that two impedance codes, which are the pull-up impedance code PCODE<0:N> and the pull-down impedance code NCODE<0:N>, are used, a semiconductor device may use one impedance code, which is either the pull-up impedance code PCODE<0:N> or the pull-down impedance code NCODE<0:N>. This is because the interface pad is only pull-up terminated or pull-down terminated depending on a termination scheme of the semiconductor device. Therefore, the impedance code generation unit 310 may be formed to generate one impedance code, which is either the pull-up impedance code PCODE<0:N> or the pull-down impedance code NCODE<0:N>, and the impedance code modification unit 330 may be formed to modify the impedance code value of one impedance code PCODE<0:N> or NCODE<0:N>. That termination circuit 380 may be formed to receive one modified impedance code, which is either modified pull-up impedance code P_NEW<0:N> or the modified pull-down impedance code N_NEW<0:N>, and terminate the interface pad through any one between pull-up termination and pull-down termination.

FIG. 4 is a block diagram illustrating the impedance code generation circuit 300 shown in FIG. 3 in accordance with another exemplary embodiment of the present invention.

Referring to FIG. 4, the set value generation unit 420 may include a pull-up set value generator 421 and a pull-down set value generator 422. The pull-up set value generator 421 generates a set value CNT_P<0:3> that corresponds to the pull-up impedance code PCODE<0:N>, and the pull-down set value generator 422 generates a set value CNT_N<0:3> that corresponds to the pull-down impedance code NCODE<0:N>.

The pull-up set value generator 421 counts the set value CNT_P<0:3> in response to the active pulse ACTIVE_P that is enabled in the presence of a particular address combination. A signal ADD1 in the drawing is a signal enabled when multi-bit address signals have a particular combination. The pull-up set value generator 421 counts the active pulse ACTIVE_P and generates the set value CNT_P<0:3> when the signal ADD1 and the active pulse ACTIVE_P are simultaneously enabled.

The pull-down set value generator 422 counts the set value CNT_N<0:3> in response to the active pulse ACTIVE_P that is enabled in the presence of a particular address combination that is different from the address combination used in the pull-up set value generator 421. A signal ADD2 in the drawing is a signal enabled when multi-bit address signals have a particular combination. The pull-down set value generator 422 counts the active pulse ACTIVE_P and generates the set value CNT_N<0:3> when the signal ADD2 and the active pulse ACTIVE_P are simultaneously enabled.

Since the embodiment of FIG. 4 is the same as the embodiment of FIG. 3 except that the set value CNT_P<0:3> corresponding to the pull-up impedance code PCODE<0:N> and the set value CNT_N<0:3> corresponding to the pull-down impedance code NCODE<0:N> are separately generated, further description on it is omitted here.

According to the embodiment of FIG. 4, the set value CNT_P<0:3> and the set value CNT_N<0:3> may be separately generated based on different address combinations. Therefore, the pull-up impedance code PCODE<0:N> and the pull-down impedance code NCODE<0:N> may be independently controlled and an impedance value may be accurately corrected based on the independent control of the pull-up impedance code PCODE<0:N> and the pull-down impedance code NCODE<0:N>.

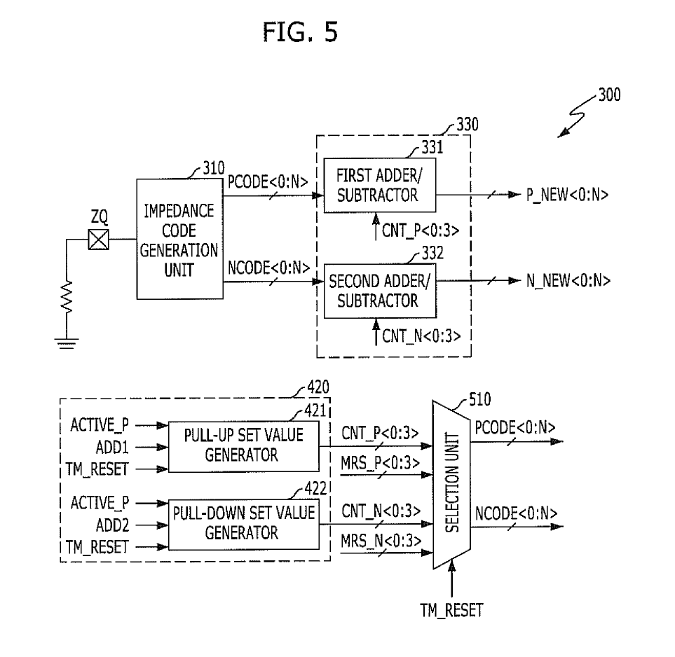

FIG. 5 is a block diagram illustrating an impedance code generation circuit 300 shown in FIG. 3 in accordance with yet another exemplary embodiment of the present invention.

Referring to FIG. 5, the impedance code generation circuit 300 according to the embodiment of FIG. 4 further includes a selection unit 510.

The selection unit 510 transfers the set values CNT_P<0:3> and CNT_N<0:3> that are generated in the set value generation unit 420 to the impedance code modification unit 330 while the reset signal TM_RESET is enabled, that is, in a mode while a set value is generated based on a counting method. While the reset signal TM_RESET is disabled, the selection unit 510 transfers set values MRS_P<0:3> and MRS_N<0:3> that are set by a Mode Register Set (MRS) to the impedance code modification unit 330.

The generation of the set values CNT_P<0:3> and CNT_N<0:3> according to the counting method aims to adjust the impedance value of the termination circuit 380 into the optimal set values by variously modifying the set value during a test. After the optimal set values CNT_P<0:3> and CNT_N<0:3> are detected through the counting method, the impedance value of the termination circuit 380 during a normal operation may be optimized, too, by using such a device as the mode resister set and inputting the optimal set values, that are detected during the test, during the normal operation. That is, the set values MRS_P<0:3> and MRS_N<0:3> of FIG. 5 is inputted from the mode resister set to optimize the impedance value of the termination circuit 380 during the normal mode.

According to an embodiment of the present invention, an impedance code may increase or decrease by counting an external signal that is inputted from the outside of a semiconductor device. Therefore, when a termination impedance value is different from a target impedance value, the difference may be easily corrected.

While the present invention has been described with respect to the specific embodiments, it will be apparent to those skilled in the art that various changes and modifications may be made without departing from the spirit and scope of the invention as defined in the following claims.

What is claimed is:

1. An impedance code generation circuit, comprising:
an impedance code generation unit configured to generate an impedance code;
a set value generation unit configured to generate a set value by counting an external signal; and
an impedance code modification unit configured to generate a modified impedance code by performing a logic operation on the set value and the impedance code.

2. The impedance code generation circuit of claim 1, wherein the set value generation unit counts the external signal in a test mode and initializes the set value at a moment when the test mode begins.

3. The impedance code generation circuit of claim 1, wherein the impedance code modification unit generates the modified impedance code by adding the set value to the impedance code or subtracting the set value from the impedance code.

4. The impedance code generation circuit of claim 1, wherein the impedance code modification unit determines whether to perform an addition operation or a subtraction operation in response to one bit of the set value, and the impedance code modification unit adds remaining bits of the set value to the impedance code or subtracts the remaining bits of the set value from the impedance code based on a determined result.

5. The impedance code generation circuit of claim 1, wherein the impedance code includes a pull-up impedance code and a pull-down impedance code, the set value includes a pull-up set value and a pull-down set value and the modified impedance code includes a modified pull-up impedance code and a modified pull-down impedance code, corresponding to the pull-up impedance code and the pull-down impedance code, respectively.

6. The impedance code generation circuit of claim 5, wherein the set value generation unit generates at least one of the pull-up set value and the pull-down set value in response to the external signal; and
the impedance code modification unit generates the modified pull-up impedance code by performing a logic operation on the pull-up set value and the pull-up impedance code or generates the modified pull-down impedance code by performing a logic operation on the pull-down set value and the pull-down impedance code.

7. The impedance code generation circuit of claim 1, further comprising:
a mode resister set configured to store the set value; and
a selection unit configured to select one between the set value and a stored set value of the mode register set in response to a test mode signal and transfer a selected value as the set value to the impedance code modification unit.

8. A semiconductor memory device, comprising:
an impedance code generation unit configured to generate an impedance code;
a set value generation unit configured to generate a set value by counting an external signal;
an impedance code modification unit configured to generate a modified impedance code by performing a logic operation on the set value and the impedance code; and
a termination circuit configured to determine an impedance value of an interface pad based on the modified impedance code.

9. The semiconductor memory device of claim 8, wherein the external signal includes an active signal of the semiconductor memory device.

10. The semiconductor memory device of claim 9, wherein the termination circuit includes at least one of a pull-up termination unit coupled between a pull-up terminal and the interface pad and a pull-down termination unit coupled between a pull-down terminal and the interface pad.

11. The semiconductor memory device of claim 10, wherein the set value generation unit generates at least one of pull-up and pull-down set values as the set value in response to the active signal and an address of the semiconductor memory device.
